(19) United States
(12) Patent Application Publication
(10) Pub. No.: US 2015/0036031 A1
(43) Pub. Date: Feb. 5, 2015

(54) SOLID-STATE IMAGING DEVICE, METHOD OF MANUFACTURING SOLID-STATE IMAGING DEVICE, AND CAMERA MODULE

(71) Applicant: Kabushiki Kaisha Toshiba, Minato-ku (JP)

(72) Inventor: Masaki KAMIMURA, Oita-shi (JP)

(73) Assignee: Kabushiki Kaisha Toshiba, Minato-ku (JP)

(21) Appl. No.: 14/197,675

(22) Filed: Mar. 5, 2014

(30) Foreign Application Priority Data
Aug. 2, 2013 (JP) 2013-161853

(51) Int. Cl. H01L 31/0216; H04N 5/361; H01L 31/18

(52) U.S. Cl. CPC H01L 31/02164; H01L 31/18; H04N 5/361
USPC 348/294; 257/43; 438/72

(57) ABSTRACT

According to one embodiment of the present invention, a solid-state imaging device is provided. The solid-state imaging device includes a photoelectric conversion element, a first insulating film, a metal oxide film, an antireflection film, and a second insulating film. The photoelectric conversion element photoelectrically converts incident light into charges and stores the converted charges. The first insulating film is provided on a light-receiving surface of the photoelectric conversion element. The metal oxide film is provided on a light-receiving surface of the first insulating film. The antireflection film is provided on a light-receiving surface of the metal oxide film. The second insulating film is formed between the metal oxide film and the antireflection film, and has a thickness of 1 nm or more and 10 nm or less.

### CROSS-REFERENCE TO RELATED APPLICATION

This application is based upon and claims the benefit of priority from Japanese Patent Application No. 2013-161853, filed on Aug. 2, 2013; the entire contents of which are incorporated herein by reference.

### FIELD

Embodiments described herein relate generally to a solid-state imaging device, a method of manufacturing solid-state imaging device, and a camera module.

### BACKGROUND

Conventionally, an electronic device such as a digital camera or a mobile terminal with camera is provided with a camera module including a solid-state imaging device. The solid-state imaging device has multiple photoelectric conversion elements arranged two-dimensionally corresponding to each pixel of a captured image. Each of the photoelectric conversion elements photoelectrically converts incident light into charges (e.g., electrons) in an amount according to the amount of the received light, and stores the charges as information indicating brightness of each pixel.

In the solid-state imaging device described above, charges might be stored on the photoelectric conversion elements independently of the presence of the incident light, due to a crystal defect on the light-receiving surface of the photoelectric conversion element or thermoelectric conversion. Such charges might be detected as dark current upon an output of a captured image, and might appear in the captured image as white blemish. Therefore, the solid-state imaging device needs to reduce the dark current.

### BRIEF DESCRIPTION OF THE DRAWINGS

FIG. 1 is a block diagram of a schematic configuration of a digital camera including a solid-state imaging device according to an embodiment;

FIG. 2 is a block diagram of a schematic configuration of the solid-state imaging device according to the embodiment;

FIG. 3 is a cross-sectional explanatory view illustrating a part of an image sensor according to the embodiment;

FIG. 4A is an explanatory view of the case where a second Si oxide film is not provided according to the embodiment;

FIG. 4B is an explanatory view of the case where the second Si oxide film is provided according to the embodiment;

FIG. 5 is a graph illustrating an experimental result involved with a relationship between a thickness of the second Si oxide film and dark current according to the embodiment;

FIG. 6 is a graph illustrating an experimental result involved with a relationship between a thickness of the second Si oxide film and flat band voltage according to the embodiment;

FIG. 7 is a graph illustrating an experimental result involved with a relationship between a thickness of the second Si oxide film and an amount of incident light according to the embodiment; and

FIGS. 8A to 10C are schematic cross-sectional views illustrating a manufacturing process of the solid-state imaging device according to the embodiment.

### DETAILED DESCRIPTION

According to one embodiment of the present invention, a solid-state imaging device is provided. The solid-state imaging device includes a photoelectric conversion element, a first insulating film, a metal oxide film, an antireflection film, and a second insulating film. The photoelectric conversion element photoelectrically converts incident light into charges and stores the converted charges. The first insulating film is provided on a light-receiving surface of the photoelectric conversion element. The metal oxide film is provided on a light-receiving surface of the first insulating film. The antireflection film is provided on a light-receiving surface of the metal oxide film. The second insulating film is provided between the metal oxide film and the antireflection film with a thickness of 1 nm or more and 10 nm or less.

A solid-state imaging device, a method of manufacturing the solid-state imaging device, and a camera module according to an embodiment will be described below in detail with reference to the accompanying drawings. Note that the embodiment does not limit the present invention.

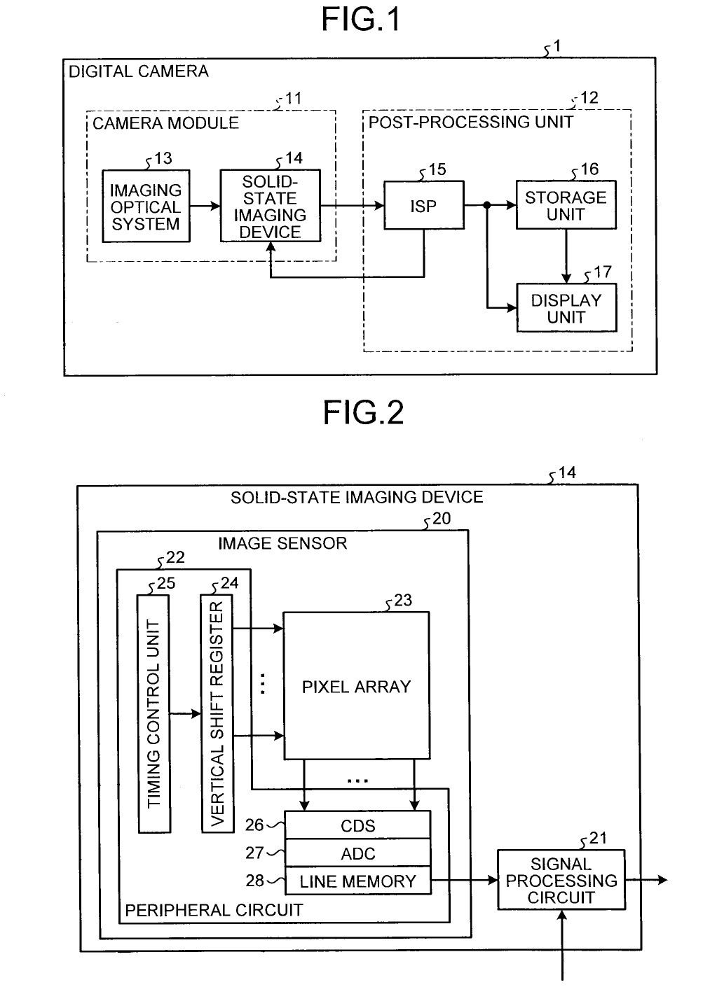

FIG. 1 is a block diagram illustrating a schematic configuration of a digital camera 1 including a solid-state imaging device 14 according to the embodiment. As illustrated in FIG. 1, the digital camera 1 includes a camera module 11 and a post-processing unit 12.

The camera module 11 includes an imaging optical system 13 and the solid-state imaging device 14. The imaging optical system 13 receives light from a subject and forms a subject image. The solid-state imaging device 14 captures the subject image, imaged by the imaging optical system 13, and outputs an image signal obtained by the image-capture to the post-processing unit 12. The camera module 11 is applied to, besides the digital camera 1, electronic device such as a mobile terminal with camera.

The post-processing unit 12 includes an ISP (Image Signal Processor) 15, a storage unit 16, and a display unit 17. The ISP 15 performs a signal process to the image signal inputted from the solid-state imaging device 14. The ISP 15 executes a high-quality process including a noise eliminating process, a defective pixel correcting process, and a resolution converting process.

The ISP 15 outputs the image signal, which has undergone the signal process, to the storage unit 16, the display unit 17, and a later-described signal processing circuit 21 (FIG. 2) mounted in the solid-state imaging device 14 in the camera module 11. The image signal fed back to the camera module 11 from the ISP 15 is used to adjust and control the solid-state imaging device 14.

The storage unit 16 stores the image signal inputted from the ISP 15 as an image. The storage unit 16 outputs the image signal to the display unit 17 in conformity with a user operation or the like. The display unit 17 displays the image in conformity with the image signal received from the ISP 15 or the storage unit 16. The display unit 17 is, for example, a liquid crystal display.

Next, the solid-state imaging device 14 mounted to the camera module 11 will be described with reference to FIG. 2. FIG. 2 is a block diagram of a schematic configuration of the solid-state imaging device 14 according to the embodiment. As illustrated in FIG. 2, the solid-state imaging device 14 includes an image sensor 20, and the signal processing circuit 21.

This embodiment describes the case in which the image sensor 20 is a back surface irradiation type CMOS (Complementary Metal Oxide Semiconductor) image sensor having a wiring layer formed on the side reverse to the side where the incident light from the photoelectric conversion element, which photoelectrically converts the incident light, enters.

The image sensor 20 according to the present embodiment is not limited to the back surface irradiation type CMOS image sensor. The image sensor 20 may be any image sensors including a front surface irradiation type CMOS image sensor, and a CCD (Charge Coupled Device) image sensor.

The image sensor 20 includes a peripheral circuit 22 and a pixel array 23. The peripheral circuit 22 includes a vertical shift resister 24, a timing control unit 25, a CDS (correlated double sampling unit) 26, an ADC (analog-digital conversion unit) 27, and a line memory 28.

The pixel array 23 is provided on an imaging region of the image sensor 20. The pixel array 23 has the multiple photoelectric conversion elements that are photodiodes corresponding to each pixel of the captured image. The multiple photoelectric conversion elements are arranged in the horizontal direction (in the row direction) and in the vertical direction (in the column direction) in a two-dimensional array (matrix array). Each photoelectric conversion element on the pixel array 23 generates signal charges (e.g., electrons) according to the amount of the incident light, and stores the generated charges.

The timing control unit 25 is a processing unit outputting a pulse signal, serving as a reference of an operation timing, to the vertical shift resister 24. The vertical shift register 24 is a processing unit outputting to the pixel array 23 a selection signal for selecting, one by one on the column basis, the photoelectric conversion element from which the signal charges are read, out of the multiple photoelectric conversion elements arranged in an array (matrix).

The pixel array 23 outputs the signal charges, which are stored in each of the selected photoelectric conversion elements on the column basis by the selection signal inputted from the vertical shift register 24, to the CDS 26 from the photoelectric conversion element as a pixel signal indicating brightness of each pixel.

The CDS 26 is a processing unit that eliminates noise from the pixel signal inputted from the pixel array 23 by correlated double sampling, and outputs the resultant to the ADC 27. The ADC 27 converts the analog pixel signal inputted from the CDS 26 into a digital pixel signal, and outputs the converted signal to the line memory 28. The line memory 28 temporarily stores the pixel signal inputted from the ADC 27, and outputs the held pixel signal to the signal processing circuit 21 for each row of the photoelectric conversion elements on the pixel array 23.

The signal processing circuit 21 performs a predetermined signal process to the pixel signal inputted from the line memory 28, and outputs the resultant signal to the post-processing unit 12. The signal processing circuit 21 performs a signal process, such as a lens shading correction, defect correction, and noise eliminating process, to the pixel signal.

As described above, in the image sensor 20, the multiple photoelectric conversion elements arranged on the pixel array 23 photoelectrically convert the incident light into the signal charges in an amount corresponding to the amount of the received light, and store the charges, and then, the peripheral circuit 22 reads the signal charges stored in each photoelectric conversion element as the pixel signal. Thus, the image sensor 20 can capture an image.

In the image sensor 20 described above, the charges might be stored in the photoelectric conversion element that does not receive the incident light. This is caused by an interface state due to a crystal defect, deposition of contaminated materials, or thermoelectric conversion, on an end face (hereinafter referred to as a “light-receiving surface”) of the photoelectric conversion element on which the incident light is introduced.

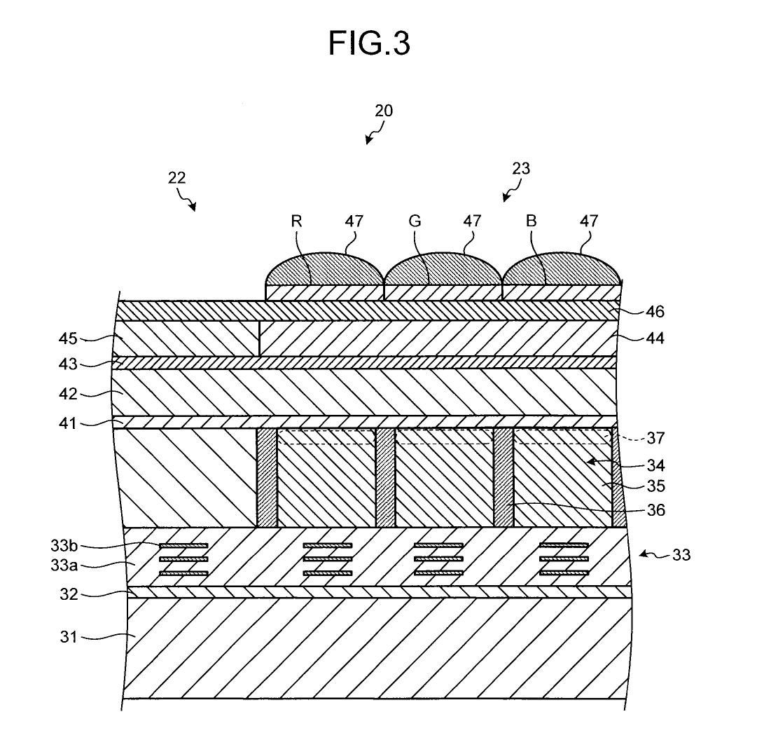

The charges become dark current, and flow into the peripheral circuit 22 from the pixel array 23, when the peripheral circuit 22 reads the pixel signal. This dark current might appear on the captured image as a white blemish. In the solid-state imaging device 14 according to the embodiment, the image sensor 20 is configured to prevent the dark current. The cross-sectional structure of the image sensor 20 will be described next with reference to FIG. 3.

FIG. 3 is a cross-sectional explanatory view illustrating a part of the image sensor 20 according to the embodiment. FIG. 3 schematically illustrates the cross-section of the image sensor 20 on the boundary between the pixel array 23 and the peripheral circuit 22.

As illustrated in FIG. 3, the image sensor 20 includes an adhesive layer 32, a multi-layer wiring layer 33, photoelectric conversion elements 34, a first Si (silicon) oxide film 41, a fixed charge layer 42, and a second Si oxide film 43, those of which are sequentially stacked on a support substrate 31.

The image sensor 20 also includes a Si nitride film 44 on the region, which becomes the pixel array 23, on the second Si oxide film 43, and a light-shielding film 45 on the region, which becomes the peripheral circuit 22, on the second Si oxide film 43.

The top surfaces of the Si nitride film 44 and the light-shielding film 45 are covered by a protection film 46 made of silicon nitride. Color filters R, G, and B are formed on the position opposite to each photoelectric conversion element 34 on the protection film 46, and a microlens 47 is provided on each of the color filters R, G, and B.

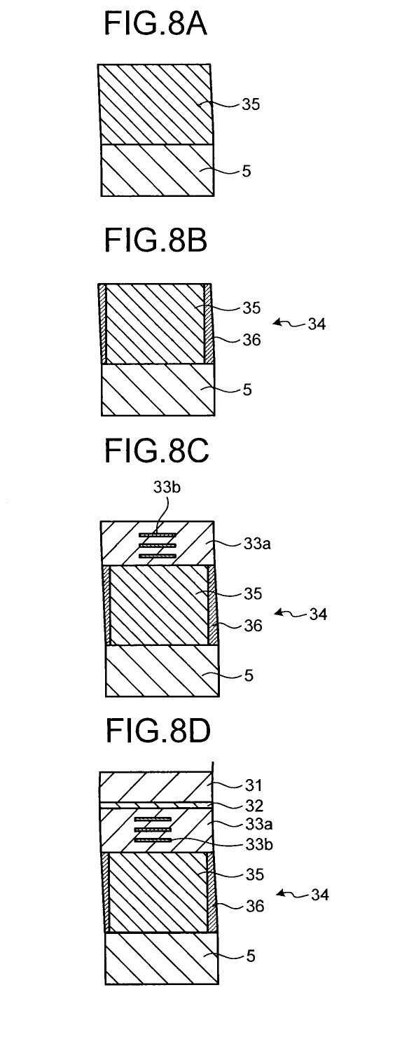

The support substrate 31 is a silicon wafer, for example. The support substrate 31 is a substrate that supports a semiconductor substrate 5 (see FIG. 8) during a process of polishing the semiconductor substrate, on which the photoelectric conversion element 34 and the multi-layer wiring layer 33 are formed, to reduce the thickness of the semiconductor substrate 5 in order to expose the light-receiving surface of the photoelectric conversion element 34. The adhesive layer 32 is a layer of an adhesive that bonds the support substrate 31 and the semiconductor substrate 5.

The multi-layer wiring layer 33 includes, for example, an interlayer insulating film 33a made of silicon oxide, and a multi-layer wiring 33b that is provided in the interlayer insulating film 33a for reading the photoelectrically converted signal charges and transmitting a drive signal or other signals to each circuit element in the peripheral circuit 22.

The photoelectric conversion element 34 includes, for example, an N-type Si region 35 into which an N-type impurity such as phosphor (P) is doped, and a P-type Si region 36 into which a P-type impurity such as boron (B) is doped. The P-type Si region 36 is formed to enclose the N-type Si region 35 viewed from top, and functions as an element isolation region for electrically isolating the photoelectric conversion elements 34 from one another.

The P-type Si region 36 is formed such that the concentration of the P-type impurity becomes low on the portion closer to the boundary with the N-type Si region 35. In the photoelectric conversion element 34, a photodiode is formed by PN junction generated on the boundary between the P-type Si region 36 and the N-type Si region 35. The photodiode photoelectrically converts the light incident from the microlens 47 into signal charges (electrons) in an amount corresponding to the amount of the received light, and stores the converted charges into the N-type Si region 35.

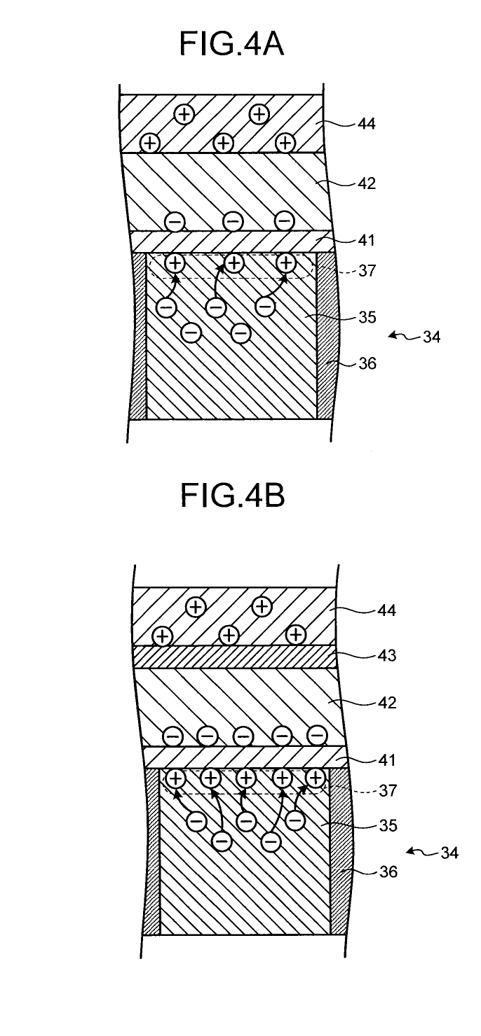

A hole storage region 37 is formed in the vicinity of the light-receiving surface of the N-type Si region 35. The hole storage region 37 stores positive fixed charges (holes) formed by inverting the electric property due to the influence of the negative fixed charges held by the later-described fixed charge layer 42. The operation and effect brought by the formation of the hole storage region 37 will be described in detail with reference to FIGS. 4A and 4B.

The first Si oxide film 41 is a thin film with a thickness of 1 nm to 10 nm. This film is provided to prevent the increase in the interface state on the light-receiving surface of the N-type Si region 35 by reducing a dangling bond generated on the light-receiving surface of the N-type Si region 35.

The formation of the first Si oxide film 41 can prevent the generation of electrons, independently of the presence of the incident light, caused by the interface state on the light-receiving surface of the N-type Si region 35. Accordingly, the dark current can be reduced.

The fixed charge layer 42 has a thickness of 10 nm or less for holding the electrons that are the negative fixed charges. This layer is provided to form the hole storage region 37 near the light-receiving surface of the N-type Si region 35.

The fixed charge layer 42 is a metal oxide film formed by any one of Hf (hafnium), Al (aluminum), Zr (zirconium), Ti (titanium), Ta (tantalum), and Ru (ruthenium), for example.

The fixed charge layer 42 may have a stacked structure including films selected from oxides of Hf, Al, Zr, Ti, Ta, and Ru. The fixed charge layer 42 may also be made of a film having a silicate structure, selected from oxides of Hf, Al, Zr, Ti, Ta, and Ru, or may have a stacked structure of these films.

The second Si oxide film 43 is a thin film with a thickness of 1 nm to 10 nm, preferably 2 nm to 5 nm. This film is provided to prevent the decrease of electrons held in the fixed charge layer 42 caused by the Si nitride film 44 formed on the second oxide film 43.

In the image sensor 20, the formation of the second Si oxide film 43 on the fixed charge layer 42 can further reduce the dark current. The operation and effect brought by the formation of the second Si oxide film 43 will be described in detail with reference to FIGS. 4A and 4B.

The Si nitride film 44 is a thin film having a function of an antireflection film for preventing the reflection of light incident on the photoelectric conversion element 34 from the microlens 47. The light-shielding film 45 is a thin film that shields the light incident on the pixel array 23 from the top surface of the peripheral circuit 22. The light-shielding film 45 is a metal film made of Al or Ti, for example.

The color filters R, G, and B transmit incident light of any one of three primary colors that are red, green, and blue. The microlens 47 is a plano-convex lens that collects the light incident on the pixel array 23 on the photoelectric conversion element 34.

The operation and effect of the hole storage region 37 and the second Si oxide film 43 will be described with reference to FIGS. 4A and 4B. In order to clarify the effect brought by the formation of the second Si oxide film 43, the case where the second Si oxide film 43 is not provided is described first, and then, the case where the second Si oxide film 43 is provided will be described.

FIG. 4A is an explanatory view of the case where the second Si oxide film 43 according to the embodiment is not provided, while FIG. 4B is an explanatory view of the case where the second Si oxide film 43 according to the embodiment is provided. As illustrated in FIG. 4A, the Si nitride film 44 is directly formed on the fixed charge layer 42, when the second Si oxide film 43 is not provided.

In this case, when a positive bias is applied to the N-type Si region 35 for allowing the PN junction between the P-type Si region 36 and the N-type Si region 35 to function as the photodiode, polarization occurs in the fixed charge layer 42. Thus, electrons are stored on the interface between the fixed charge layer 42 and the first Si oxide film 41.

In the N-type Si region 35, the holes in the N-type Si region 35 are attracted by the electrons stored on the fixed charge layer 42, so that the hole storage region 37 storing holes is formed in the vicinity of the light-receiving surface. According to this structure, some electrons that are generated, independently of the presence of the incident light, due to the interface state or the thermoelectric conversion are recombined with the holes stored in the hole storage region 37 in the N-type Si region 35, whereby the dark current can be reduced.

However, as illustrated in FIG. 4A, the Si nitride film 44 formed just above the fixed charge layer 42 holds holes. Therefore, when the Si nitride film 44 is directly formed on the fixed charge layer 42, some electrons held in the fixed charge layer 42 are canceled by the influence of the holes held in the Si nitride film 44, so that the electrons in the fixed charge layer 42 decrease.

With this, the holes stored in the hole storage region 37 in the N-type Si region 35 also decrease. Accordingly, the performance of reducing the dark current is deteriorated, when the Si nitride film 44 is directly formed on the fixed charge layer 42.

In view of this, in the solid-state imaging device 14 according to the embodiment, the second Si oxide film 43 is provided between the fixed charge layer 42 and the Si nitride film 44 for physically separating the fixed charge layer 42 and the Si nitride film 44 from each other as illustrated in FIG. 4B.

When the second Si oxide film 43 is provided as illustrated in FIG. 4B, the influence applied to the electrons in the fixed charge layer 42 by the holes in the Si nitride film 44 is reduced. Therefore, more electrons than in the case illustrated in FIG. 4A are held on the interface of the fixed charge layer 42 with the first Si oxide film 41.

As a result, more electrons than in the case illustrated in FIG. 4A are also stored in the hole storage region 37 in the N-type Si region 35. Accordingly, when the second Si oxide film 43 is provided, more electrons present in the N-type Si region 35 independently of the presence of the incident light are recombined with the holes in the hole storage region 37, whereby the performance of reducing the dark current can further be enhanced.

The larger the thickness of the second Si oxide film 43 is, the more the influence to the electrons in the fixed charge layer 42 by the holes in the Si nitride film 44 can be reduced. When the thickness of the second Si oxide film 43 is unnecessarily increased, the amount of light incident on the photoelectrically conversion element 34 might be reduced.

In the present embodiment, the second Si oxide film 43 is provided on the top surface of the fixed charge layer 42, the second Si oxide film 43 being formed to have a thickness capable of preventing the decrease in the amount of light incident upon the photoelectric conversion element 34, as well as capable of reducing the dark current. The thickness capable of reducing the dark current is decided based upon the result of the experiment described next.

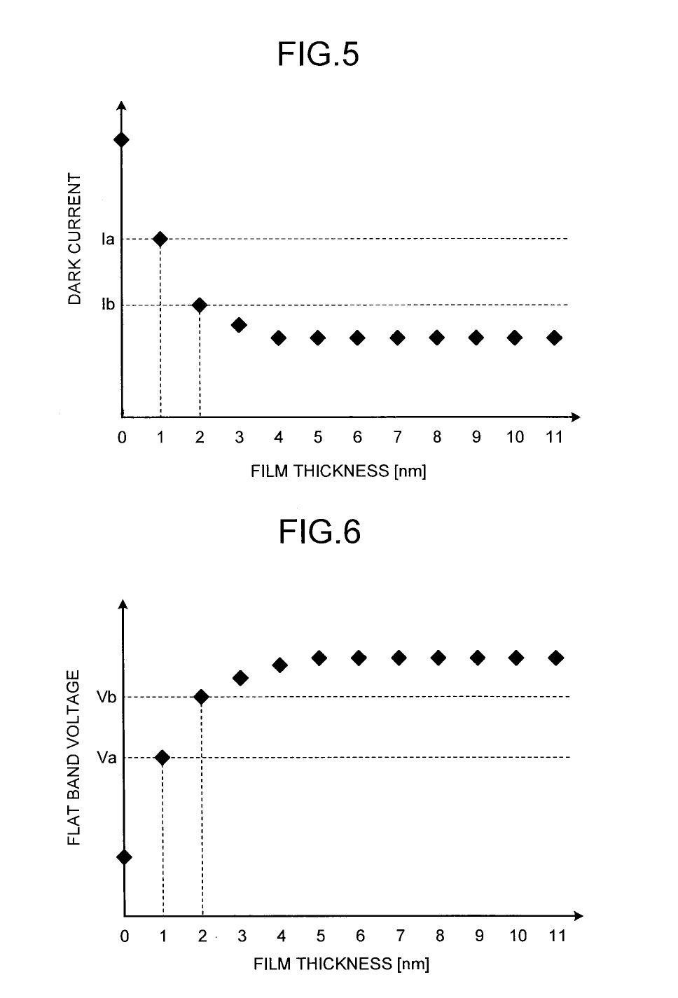

The result of the experiment involved with the thickness of the second Si oxide film 43 will next be described with reference to FIGS. 5 to 7. FIG. 5 is a graph illustrating the experimental result involved with a relationship between the thickness of the second Si oxide film 43 and dark current according to the embodiment.

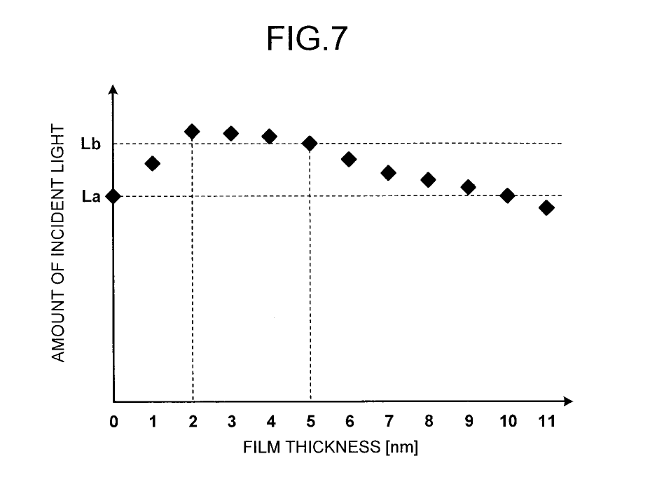

FIG. 6 is a graph illustrating the experimental result involved with a relationship between the thickness of the second Si oxide film 43 and flat band voltage according to the embodiment. The flat band voltage here is a flat band voltage of a transfer transistor that transfers the signal charge, which is photoelectrically converted by the photoelectric conversion element 34, to a floating diffusion. FIG. 7 is a graph illustrating the experimental result involved with a relationship between the thickness of the second Si oxide film 43 and an amount of incident light according to the embodiment.

As illustrated in FIG. 5, in the experiment, the dark current was measured by changing the thickness of the second Si oxide film 43 from 0 nm (the state in which the second Si oxide film 43 is not provided) to 11 nm. The obtained experimental result shows that the dark current gradually decreases with the increase in the thickness of the second Si oxide film 43, and the dark current converges to the minimum value when the thickness becomes 4 nm or more.

A value Ia of the dark current in FIG. 5 indicates an upper-limit value of a permitted value of the dark current, while a value Ib is an upper-limit value of the preferable value of the dark current. It is found from FIG. 5 that the thickness of the second Si oxide film 43 is desirably 1 nm or more, more desirably 2 nm or more.

As illustrated in FIG. 6, in the experiment, the flat band voltage was measured by changing the thickness of the second Si oxide film 43 from 0 nm (the state in which the second Si oxide film 43 is not provided) to 11 nm. The obtained experimental result shows that the flat band voltage gradually increases with the increase in the thickness of the second Si oxide film 43, and the flat band voltage converges to the maximum value when the thickness becomes 5 nm or more. When the flat band voltage measured in this experiment is high, the number of electrons held in the fixed charge layer 42 is large.

A value Va of the flat band voltage illustrated in FIG. 6 indicates a lower-limit value of a permitted value of the flat band voltage, while a value Vb indicates a lower-limit value of a preferable value of the flat band voltage. It is found from FIG. 6 that the thickness of the second Si oxide film 43 is desirably 1 nm or more, more desirably 2 nm or more.

In the experiment in FIG. 7, the amount of light incident on the photoelectric conversion element 34 was measured by changing the thickness of the second Si oxide film 43 from 0 nm (the state in which the second Si oxide film 43 is not provided) to 11 nm. A value La of the amount of incident light illustrated in FIG. 7 indicates a lower-limit value of a permitted value of the amount of incident light, while a value Lb indicates a lower-limit value of a preferable value of the amount of incident light.

The experimental result shows that the amount of incident light becomes the maximum, when the thickness of the second Si oxide film 43 is 2 nm. Specifically, the amount of incident light decreases with the thickness of the second Si oxide film 43 being decreased from 2 nm, and decreases with the thickness being increased from 2 nm.

If the thickness of the second Si oxide film 43 is within the range of 1 nm or more and 10 nm or less, the amount of incident light becomes more than the amount of incident light in the case where the second Si oxide film 43 is not provided. It is found from this result that the thickness of the second Si oxide film 43 is desirably 1 nm or more and 10 nm or less, more desirably 2 nm or more and 5 nm or less.

In the present embodiment, the thickness of the second Si oxide film 43 is set to be 1 nm or more and 10 nm or less, more preferably 2 nm or more and 5 nm or less based upon three experimental results. According to this structure, the amount of light incident upon the photoelectric conversion element 34 can be reduced, as well as the dark current can be reduced.

A method of manufacturing the solid-state imaging device 14 will be described below with reference to FIGS. 8A to 10C. The method of manufacturing the components other than the pixel array 23 in the solid-state imaging device 14 is the same as the method for a popular CMOS image sensor. Therefore, the method of manufacturing the pixel array 23 in the solid-state imaging device 14 will only be described below.

FIGS. 8A to 10C are cross-sectional views schematically illustrating a manufacturing process of the solid-state imaging device 14 according to the embodiment. FIGS. 8A to 100 selectively illustrate the manufacturing process of the portion corresponding to one pixel in the pixel array 23.

As illustrated in FIG. 8A, the N-type Si region 35 is formed on the semiconductor substrate 5 such as a Si wafer for manufacturing the pixel array 23. In this case, a Si layer into which the N-type impurity such as P (phosphor) is doped is epitaxially grown on the semiconductor substrate 5 to form the N-type Si region 35. The N-type Si region 35 may be formed by injecting the N-type impurity into the Si wafer by an ion implantation, and performing an annealing process.

Next, as illustrated in FIG. 8B, the P-type impurity such as B (boron) is injected into the semiconductor substrate 5 from above on the position where the element isolation region is to be formed in the N-type Si region 35 by the ion implantation, and then, the annealing process is carried out. Thus, the P-type Si region 36 is formed.

The P-type Si region 36 may be formed such that an opening is formed on the position where the element isolation region is to be formed in the N-type Si region 35, and then, the Si layer having the impurity such as P doped in the opening is epitaxially grown. According to this process, the multiple photoelectric conversion elements 34, which are electrically isolated from one another by the P-type Si region 36, are formed in a matrix, viewed from top, on the pixel array 23.

Subsequently, the multi-layer wiring layer 33 (see FIG. 3) is formed on the top surface of the photoelectric conversion element 34. In this case, as illustrated in FIG. 8C, the multi-layer wiring layer 33 is formed by repeating a process of forming the interlayer insulating film 33a such as the Si oxide film, a process of forming a predetermined wiring pattern on the interlayer insulating film 33a, and a process of burying Cu into the wiring pattern to form the multi-layer wiring 33b. Thereafter, as illustrated in FIG. 8D, the adhesive layer 32 is formed by applying the adhesive agent on the top surface of the multi-layer wiring layer 33, and the support substrate 31 such as a Si wafer is bonded on the top surface of the adhesive layer 32.

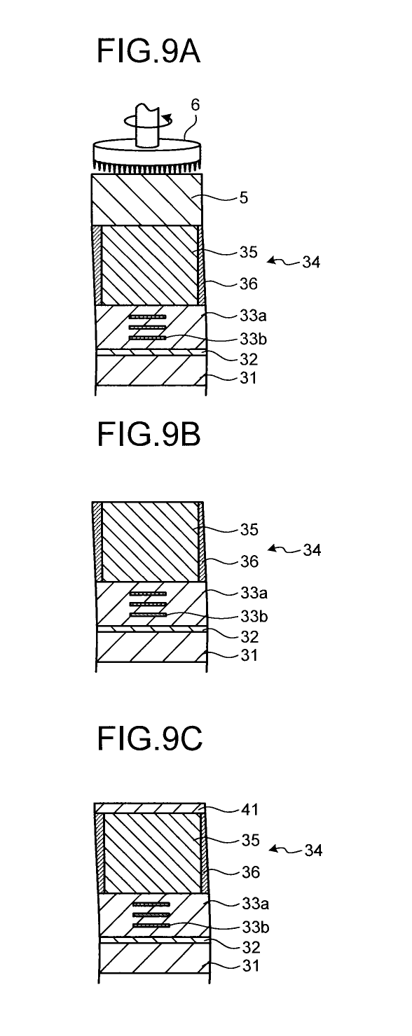

As illustrated in FIG. 9A, the structure illustrated in FIG. 8D is turned upside down, and then, the semiconductor substrate 5 is polished from its back surface (here, the top surface) by a polishing device 6 such as a grinder to reduce the thickness of the semiconductor substrate 5 to a predetermined thickness.

Then, the back surface of the semiconductor substrate 5 is further polished by a CMP (Chemical Mechanical Polishing), in order to expose the back surface (here, the top surface) of the N-type Si region 35 as illustrated in FIG. 9B. In this case, a dangling bond is generated on the top surface, which is the polished surface, of the N-type Si region 35, whereby the interface state occurs.

As described above, the N-type Si region 35 is the hole storage region 37 that stores the photoelectrically converted electrons, and the exposed top surface serves as the light-receiving surface of the photoelectric conversion element 34. When the interface state occurs on the light-receiving surface of the photoelectric conversion element 34, the electrons generated due to the interface state independently of the incident light are stored in the N-type Si region 35. The stored electrons might cause the dark current, and thus unpreferable.

In view of this, during the method of manufacturing the solid-state imaging device 14 according to the embodiment, the first Si oxide film 41 with a thickness of 3 nm or less is formed on the light-receiving surface of the photoelectric conversion element 34 as illustrated in FIG. 9C.

An ALD (Atomic Layer Deposition) process is employed for forming the first Si oxide film 41. The ALD process is suitable for the formation of the first Si oxide film 41, since it has the advantages described below. Specifically, the ALD process can avoid the problem of elution of Cu, which is used for the multi-layer wiring 33b that has already been formed during the formation of the first Si oxide film 41, since the first Si oxide film 41 can be formed at about 400° C. In addition, this process can form the more stable Si interface than that formed by the other low-temperature film-forming method such as a plasma CVD (Chemical Vapor Deposition) process, and has excellent thickness control during the formation of a thin film.

As described above, the formation of the first Si oxide film 41 on the light-receiving surface of the photoelectric conversion element 34 can prevent the occurrence of the interface state on the top surface of the N-type Si region 35, whereby the dark current can be reduced. Since the first Si oxide film 41 has the thickness of 3 nm or less, it can control the reflection and refraction of the incident light to be a negligible level.

In the present embodiment, the first Si oxide film 41 is formed on the top surface of the N-type Si region 35 and the top surface of the P-type Si region 36. However, the generation of negative charges that causes the dark current can be prevented, so long as the first Si oxide film 41 is formed on at least the top surface of the N-type Si region 35.

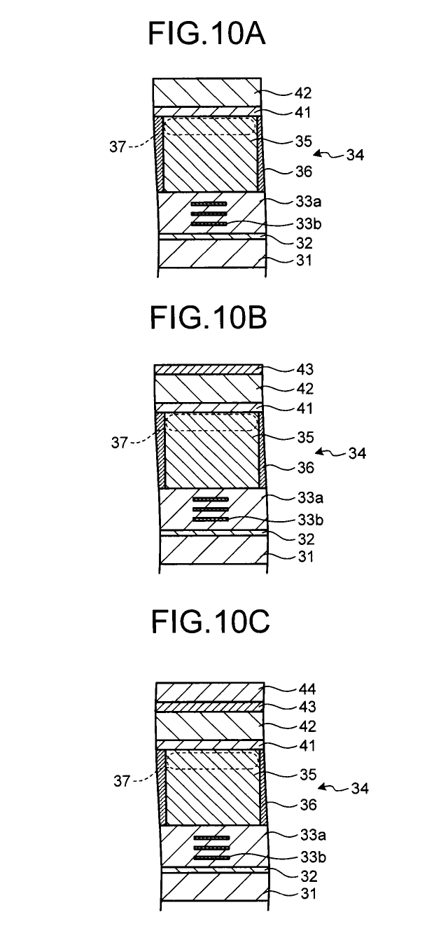

Next, as illustrated in FIG. 10A, the fixed charge layer 42 holding the negative fixed charges (electrons) is formed on the top surface of the first Si oxide film 41. A HfO (hafnium oxide) film with a thickness of 10 nm or less is formed as the fixed charge layer 42, for example.

The ALD process is used to form the fixed charge layer 42. The ALD process is suitable for the formation of the fixed charge layer 42, since it has the advantages described below. Specifically, the ALD process can avoid the problem of elution of Cu, which is used for the multi-layer wiring 33b that has already been formed during the formation of the first Si oxide film 41, since the fixed charge layer 42 can be formed at about 400° C. In addition, this process has excellent thickness control during the formation of a thin film.

At least a part of HfO is crystallized to be a silicate crystal by the processing temperature during the formation or the processing temperature during the subsequent formation process, and with this, the negative fixed charges are generated. The holes are attracted by the generated negative charges in the vicinity of the light-receiving surface of the N-type Si region 35, whereby the hole storage region 37 is formed.

Thus, the electrons, which are generated by a crystal defect or a heavy metal element present near the interface, and which cause the dark current, are recombined with the holes. Accordingly, the solid-state imaging device 14 can further reduce the dark current. In the present embodiment, the material of the fixed charge layer 42 is HfO. However, the fixed charge layer 42 may be made of a material containing one or more of Hf, Ti, Al, Zr, and Mg.

Thereafter, as illustrated in FIG. 10B, the second Si oxide film 43 is formed on the surface (light-receiving surface) of the fixed charge layer 42 where the incident light enters. In this case, the second Si oxide film 43 is formed by the ALD process with a thickness falling within the range of 1 nm to 10 nm, more preferably 2 nm to 5 nm.

Since the second Si oxide film 43 is formed by the ALD process, like the first Si oxide film 41, the generation of the dangling bond on the interface between the second Si oxide film 43 and the fixed charge layer 42 and the interface between the second Si oxide film 43 and the Si nitride film 44 can be prevented. Accordingly, this structure can prevent the electrons that are generated due to the interface state caused by the dangling bond from being detected as the dark current.

Thereafter, as illustrated in FIG. 10C, the second Si nitride film 44 serving as the antireflection film is formed on the surface (light-receiving surface) of the second Si oxide film 43 where the incident light enters. The Si nitride film 44 is formed by a general CVD process.

HfO used for the fixed charge layer 42 has high refractive index, so that the function as the antireflection film can be attained only by HfO. The fixed charge layer 42, however, needs to be formed by the ALD process in order to generate stable fixed charges. However, the formation of the fixed charge layer 42 takes much time. Forming the thick film increases load on productivity.

Therefore, the present embodiment reduces the load, which increases because of the formation of the fixed charge layer 42 by the ALD process, on the productivity by the process of forming the Si nitride film 44 with the CVD process that can form the film in relatively a short time.

Thereafter, the color filters R, G, and B and the microlens 47 are sequentially formed on the top surface of the Si nitride film 44, whereby the solid-state imaging device 14 having the image sensor 20 illustrated in FIG. 3 is produced.

In the method of manufacturing the solid-state imaging device 14 according to the embodiment, the second Si oxide film 43 is formed between the fixed charge layer 42 and the Si nitride film 44 as described above. This process can prevent the composition change of the fixed charge layer 42 due to the influence of the Si nitride film 44, resulting in that the stable fixed charge layer 42 can be formed.

Accordingly, the method of manufacturing the solid-state imaging device 14 can prevent the decrease in the holes stored in the hole storage region 37 in the N-type Si region 35. Consequently, the solid-state imaging device 14 that can significantly reduce the dark current can be produced.

If the first Si oxide film 41 and the second Si oxide film 43 are formed to have the same thickness, these films can be formed under the totally same condition. Therefore, the operation efficiency of the film-forming device is enhanced, and the load on the productivity can more be reduced.

In the present embodiment, the first Si oxide film 41, the fixed charge layer 42, and the second Si oxide film 43 are all formed by the ALD process. However, at least any one of them may be formed by the ALD process.

As described above, in the solid-state imaging device according to the present embodiment, the fixed charge layer and the antireflection film are physically isolated by the silicon oxide film formed to have a thickness of 1 nm to 10 nm, more preferably 2 nm to 5 nm between the fixed charge layer and the antireflection film.

This configuration can prevent the decrease in the negative charges in the fixed charge layer caused by the positive charges in the antireflection film, thereby being capable of preventing the decrease in the positive charges on the light-receiving surface of the photoelectric conversion element. Accordingly, the dark current can further be reduced.

In addition, in the solid-state imaging device according to the present embodiment, the silicon oxide film formed between the fixed charge layer and the antireflection film has a thickness of 1 nm to 10 nm, more preferably 2 nm to 5 nm. Therefore, the solid-state imaging device can reduce the dark current, while preventing the decrease in the amount of incident light.

The solid-state imaging device according to the embodiment further includes the silicon oxide film formed on the light-receiving surface of the photoelectric conversion element. According to this configuration, the solid-state imaging device according to the embodiment can further reduce the dark current by preventing the increase in the interface state caused on the light-receiving surface of the photoelectric conversion element.

The silicon oxide film and the fixed charge layer according to the embodiment are formed by the ALD process. According to the ALD process, the silicon oxide film and the fixed charge layer can be formed at a processing temperature lower than a melting point of a metal used for the multi-layer wiring in the solid-state imaging device, for example. Accordingly, the solid-state imaging device according to the embodiment can prevent the adverse affect on the multi-layer wiring exerted by the formation of the silicon oxide film and the fixed charge layer.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solid-state imaging device comprising:
a photoelectric conversion element that photoelectrically converts incident light into charges and stores the converted charges;
a first insulating film that is provided on a light-receiving surface of the photoelectric conversion element;
a metal oxide film provided on a light-receiving surface of the first insulating film;
an antireflection film formed on a side close to a light-receiving surface of the metal oxide film; and
a second insulating film formed between the metal oxide film and the antireflection film, and having a thickness of 1 nm or more and 10 nm or less.

2. The solid-state imaging device according to claim 1, wherein
the first insulating film and the second insulating film are the same thin films with a same composition and same thickness.

3. The solid-state imaging device according to claim 1, wherein
the first insulating film and the second insulating film are a silicon oxide film.

4. The solid-state imaging device according to claim 1, wherein
the antireflection film is a silicon nitride film.

5. The solid-state imaging device according to claim 1, wherein
the second insulating film has a thickness of 2 nm or more and 5 nm or less.

6. The solid-state imaging device according to claim 1, wherein
the first insulating film and the second insulating film are thin films formed by an ALD (Atomic Layer Deposition) process.

7. The solid-state imaging device according to claim 1, wherein
the antireflection film is a thin film formed by a plasma CVD (Chemical Vapor Deposition) process.

8. The solid-state imaging device according to claim 1, wherein
the metal oxide film is any one of a hafnium oxide film, an aluminum oxide film, a zirconium oxide film, a titanium oxide film, a tantalum oxide film, and a ruthenium oxide film.

9. The solid-state imaging device according to claim 1, wherein
the metal oxide film has a stacked structure of thin films selected from a hafnium oxide film, an aluminum oxide film, a zirconium oxide film, a titanium oxide film, a tantalum oxide film, and a ruthenium oxide film.

10. The solid-state imaging device according to claim 1, wherein
the metal oxide film has a silicate structure.

11. A method of manufacturing a solid-state imaging device, the method comprising:
forming a photoelectric conversion element that photoelectrically converts incident light into charges and stores the converted charges;
forming a first insulating film on a light-receiving surface of the photoelectric conversion element;
forming a metal oxide film on a light-receiving surface of the first insulating film;
forming a second insulating film with a thickness of 1 nm or more and 10 nm or less on a light-receiving surface of the metal oxide film; and
forming an antireflection film on a light-receiving surface of the second insulating film.

12. The method of manufacturing a solid-state imaging device according to claim 10, further comprising:
forming the second insulating film having a composition and thickness same as those of the first insulating film.

13. The method of manufacturing a solid-state imaging device according to claim 10, further comprising:
forming the first insulating film by silicon oxide; and
forming the second insulating film by silicon oxide.

14. The method of manufacturing a solid-state imaging device according to claim 10, further comprising:
forming the antireflection film by silicon nitride.

15. The method of manufacturing a solid-state imaging device according to claim 10, further comprising:
forming the first insulating film by an ALD (Atomic Layer Deposition) process; and
forming the second insulating film by the ALD process.

16. The method of manufacturing a solid-state imaging device according to claim 10, further comprising:
forming the antireflection film by a plasma CVD (Chemical Vapor Deposition) process.

17. The method of manufacturing a solid-state imaging device according to claim 10, further comprising:
forming the metal oxide film by using any one of hafnium oxide, aluminum oxide, zirconium oxide, titanium oxide, tantalum oxide, and ruthenium oxide.

18. The method of manufacturing a solid-state imaging device according to claim 10, further comprising:
forming the metal oxide film by stacking thin films selected from a hafnium oxide film, an aluminum oxide film, a zirconium oxide film, a titanium oxide film, a tantalum oxide film, and a ruthenium oxide film.

19. The method of manufacturing a solid-state imaging device according to claim 10, further comprising:
forming the metal oxide film to have a silicate structure.

20. A camera module comprising:
an imaging optical system that receives light from a subject to form a subject image; and
a solid-state imaging device that captures the subject image formed by the imaging optical system, wherein
the solid-state imaging device includes:
a photoelectric conversion element that photoelectrically converts incident light into charges and stores the converted charges;
a first insulating film that is provided on a light-receiving surface of the photoelectric conversion element;
a metal oxide film provided on a light-receiving surface of the first insulating film;
an antireflection film formed on a side close to a light-receiving surface of the metal oxide film; and
a second insulating film formed between the metal oxide film and the antireflection film, and having a thickness of 1 nm or more and 10 nm or less.
